(19) United States
(12) Patent Application Publication
(10) Pub. No.: US 2025/0070002 A1
(43) Pub. Date: Feb. 27, 2025

(54) SEMICONDUCTOR PACKAGE

(71) Applicant: SAMSUNG ELECTRONICS CO., LTD., SUWON-SI (KR)

(72) Inventors: Kyungtae Kim, Suwon-si (KR); Minsoo Kim, Suwon-si (KR); Jakyoung Gu, Suwon-si (KR); Kyoungok Jung, Suwon-si (KR); Hyunwoong Han, Suwon-si (KR)

(21) Appl. No.: 18/667,800

(22) Filed: May 17, 2024

(30) Foreign Application Priority Data
Aug. 22, 2023 (KR) 10-2023-0109613

(51) Int. Cl. H01L 23/498; H01L 23/522; H01L 23/528; H01L 23/532

(52) U.S. Cl. CPC H01L 23/49816; H01L 23/5226; H01L 23/5283; H01L 23/53214; H01L 23/53228; H01L 23/53295

(57) ABSTRACT

A semiconductor package, may include: a lower redistribution structure including lower redistribution layers; a semiconductor chip on the lower redistribution structure, and electrically connected to the lower redistribution layers; connection bumps on the lower redistribution structure, and electrically connected to the lower redistribution layers; an encapsulant covering at least a portion of the semiconductor chip; an upper redistribution structure including an upper insulating layer on the semiconductor chip, and upper redistribution layers including a metal structure on the upper insulating layer; an interconnection structure that electrically connects the lower redistribution layers and the upper redistribution layer; and a metal plate on an upper surface of the metal structure, wherein the upper surface may have a first surface, a second surface around the first surface, and a third surface around the second surface, the first surface may be on the same or higher level than that of the second surface.

### CROSS-REFERENCE TO RELATED APPLICATION(S)

This application claims priority under 35 U.S.C. § 119 to Korean Patent Application No. 10-2023-0109613, filed on Aug. 22, 2023, in the Korean Intellectual Property Office, and all the benefits accruing therefrom, the entire contents of which is incorporated herein by reference in its entirety.

### BACKGROUND

The present inventive concept relates to a semiconductor package.

Semiconductor packaging technology is being actively researched in accordance with the trend for high performance and miniaturization of electronic devices. When forming a metal plate on a redistribution layer of a semiconductor package, cracks may occur in a resist used during the process.

### SUMMARY

An aspect of the present inventive concept is to provide a semiconductor package with improved reliability.

According to example embodiments of the present inventive concept, provided is a semiconductor package, the semiconductor package including: a lower redistribution structure including lower redistribution layers; a semiconductor chip on an upper surface of the lower redistribution structure, and electrically connected to the lower redistribution layers; connection bumps on a lower surface of the lower redistribution structure, and electrically connected to the lower redistribution layers; an upper redistribution structure, including an upper insulating layer on the semiconductor chip, an upper redistribution layers in the upper insulating layer, and a metal structure on the upper insulating layer; an interconnection structure electrically connecting the lower redistribution layers and the upper redistribution layer; and a metal plate on an upper surface of the metal structure, wherein the upper surface of the metal structure has a first surface in contact with the metal plate, a second surface around the first surface, and a third surface around the second surface.

According to example embodiments of the present inventive concept, provided is a semiconductor package, the semiconductor package including: a semiconductor chip; a lower redistribution structure including a lower insulating layer on a lower surface of the semiconductor chip, and lower redistribution layers electrically connected to the semiconductor chip on the lower surface of the semiconductor chip; connection bumps on a lower surface of the lower redistribution structure, and electrically connected to the lower redistribution layers; an encapsulant covering at least a portion of the semiconductor chip on an upper surface of the lower redistribution structure; an upper insulating layer on the encapsulant; upper redistribution layers including a metal structure on the upper insulating layer; a metal plate on the metal structure; and an interconnection structure penetrating through the encapsulant to electrically connect the lower redistribution layers and the upper redistribution layers, wherein the metal structure may include a first surface in contact with the metal plate, a second surface around the first surface, and a third surface surrounding the second surface and having a step difference from the second surface.

According to example embodiments of the present inventive concept, provided is a semiconductor package, the semiconductor package including: a lower redistribution structure including lower redistribution layers; a semiconductor chip on the lower redistribution structure, and electrically connected to the lower redistribution layers; connection bumps below the lower redistribution structure, and electrically connected to the lower redistribution layers; an encapsulant covering at least a portion of the semiconductor chip on the lower redistribution structure; an upper redistribution structure including an upper insulating layer on the encapsulant, and upper redistribution layers including a metal structure on the upper insulating layer; a metal plate on the metal structure; and an interconnection structure penetrating through the encapsulant to electrically connect the lower redistribution layers and the upper redistribution layers, wherein the metal structure may have a first portion in contact with the metal plate and a second portion surrounding the first portion, wherein first portion and the second portion may be spaced apart from each other.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a cross-sectional view illustrating a semiconductor package according to example embodiments;

FIG. 2A is an enlarged view of region ‘A’ and FIG. 2B is a plan view of FIG. 2A;

FIG. 3A is an enlarged view of region ‘A’ and FIG. 3B is a plan view of FIG. 3A;

FIGS. 4 to 10 are enlarged views of region ‘A’ in FIG. 1 according to example embodiments;

FIG. 11 is a cross-sectional view illustrating a semiconductor package according to example embodiments;

FIG. 12 is a cross-sectional view illustrating a semiconductor package according to example embodiments;

FIGS. 13A to 13L are enlarged views of region ‘A’ in FIG. 2 according to a process sequence; and

FIGS. 14A to 14B are enlarged views of region ‘A’ in FIG. 8 according to a process sequence.

### DETAILED DESCRIPTION

Hereinafter, embodiments of the present inventive concept will be described with reference to the attached drawings, wherein the same reference numbers refer to the same or similar elements.

Hereinafter, terms such as ‘upper,’ ‘upper portion,’ ‘upper surface,’ ‘lower,’ ‘lower portion,’ ‘lower surface,’ ‘side surface,’ and the like, may be understood in reference to the drawings, unless otherwise indicated by reference numerals.

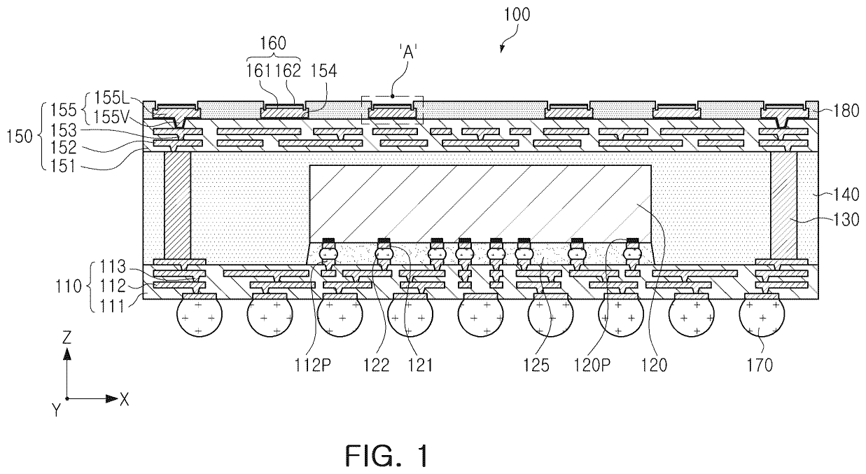

FIG. 1 is a plan view illustrating a semiconductor package according to example embodiments.

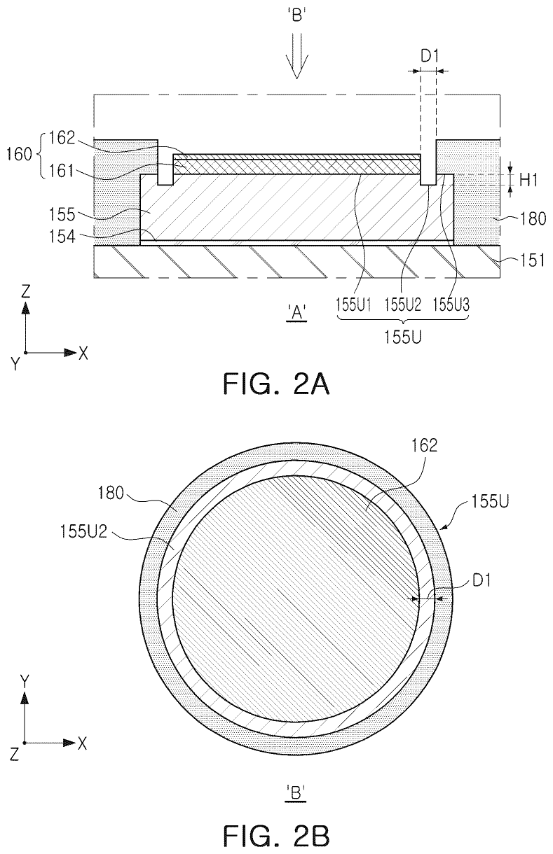

FIG. 2A and FIG. 2B are enlarged views of region ‘A’ in FIG. 1, where FIG. 2A is a cross-sectional view of region ‘A,’ and FIG. 2B is a plan view of region ‘A.’

Referring to FIGS. 1 to 2B, a semiconductor package 100 may include a lower redistribution structure 110, a semiconductor chip 120, a interconnection structure 130, an encapsulant 140, and an upper redistribution structure 150. The semiconductor package 100 may further include a metal plate 160 and a connection bump 170. In addition, the semiconductor package 100 may further include a metal seed layer 154 and a passivation layer 180.

In various embodiments, the lower redistribution structure 110 may be a support substrate, and may have an upper surface on which the semiconductor chip 120 is mounted and a lower surface opposite the upper surface. The lower redistribution structure 110 may include a lower insulating layer 111, lower redistribution layers 112, and lower redistribution vias 113, where the lower redistribution layers 112 and lower redistribution vias 113 may be embedded in the lower insulating layer 111.

In various embodiments, the lower insulating layer 111 may include a plurality of layers stacked in a vertical direction (Z-direction), and a boundary between the plurality of layers may be indistinct. The lower insulating layer 111 may include an insulating resin, where the insulating resin may include a thermosetting resin, such as an epoxy resin, a thermoplastic resin such as polyimide, or a resin impregnated with an inorganic filler, for example, prepreg, Ajinomoto Build-up Film (ABF), FR-4, BT, and the like. The lower insulating layer 111 may include a photosensitive resin such as Photoimageable Dielectric (PID).

In various embodiments, the lower redistribution layers 112 may include a plurality of lower redistribution layers located on different levels. A portion of the lower redistribution layers 112 may be adjacent to a lower surface of the lower insulating layer 111, and another portion thereof may be adjacent to an upper surface of the lower insulating layer 111. The lower redistribution layers 112 may further include a pad portion 112P disposed on the upper surface of the lower insulating layer 111. The pad portion 112P may be connected to a semiconductor chip 120 or an interconnection structure 130. The lower redistribution layers 112 may include, for example, copper (Cu), aluminum (Al), silver (Ag), tin (Sn), gold (Au), nickel (Ni), lead (Pb), and titanium (Ti), or a metal material including alloys thereof. The lower redistribution layers 112 may perform various functions depending on the design, where the lower redistribution layers 112 may include a ground (GND) pattern, a power (PWR) pattern, and/or a signal(S) pattern. The signal(S) pattern may provide a transmission path for various signals, for example, data signals, and the like, excluding the ground (GND) pattern, power (PWR) pattern, and the like.

In various embodiments, the lower redistribution vias 113 may extend through a portion of the insulating layer 111 and be electrically connected to the lower redistribution layers 112. For example, the lower redistribution vias 113 may extend through the thickness of the insulating layer 111, and interconnect lower redistribution layers 112 on different levels. The lower redistribution vias 113 may include a signal via, a ground via, and a power via. The lower redistribution vias 113 may include, for example, copper (Cu), aluminum (Al), silver (Ag), tin (Sn), gold (Au), nickel (Ni), lead (Pb), titanium (Ti), or alloys thereof. The lower redistribution vias 113 may be filled vias in which an interior of a via hole is filled with a metal material, or may be conformal vias in which a metal material extends along an inner wall of the via hole.

In various embodiments, the semiconductor chip 120 may be disposed on an upper surface of the lower redistribution structure 110, and may include a connection pad 120P electrically connected to the lower redistribution layers 112. The semiconductor chip 120 may be a bare integrated circuit (IC) without separate bumps of wiring layers, but the present inventive concept is not limited thereto, and may be a packaged-type integrated circuit. The integrated circuit of the semiconductor chip 120 may be a processor chip, such as a central processor (CPU), graphics processor (GPU), field programmable gate array (FPGA), application processor (AP), digital signal processor, cryptographic processor, microprocessor, microcontroller, and the like, but the present inventive concept is not limited thereto, and the semiconductor chip 120 may be a logic chip, such as an analog-digital converter, application specific IC (ASIC), a volatile memory such as dynamic RAM (DRAM), static RAM (SRAM), and the like, and a non-volatile memory such as phase change RAM (PRAM), magnetic RAM (MRAM), resistive RAM (RRAM), flash memory, and the like.

In various embodiments, the semiconductor chip 120 may include a first connection bump 121 and a second connection bump 122 electrically connecting the connection pad 120P to the pad portion 112P of the lower redistribution layer 112. The first connection bump 121 and the second connection bump 122 may be disposed between the pad portion 112P and the connection pad 120P. The first connection bump 121 may be in contact with the connection pad 120P, and the second connection bump 122 may be in contact with the first connection bump 121, where the first connection bump 121 and the second connection bump 122 may be sequentially stacked on the connection pad 120P. The second connection bump 122 may be in contact with an upper surface of the pad portion 112P. The connection bump 122 may contact the pad portion 112P on the upper surface of the pad portion 112P. The first connection bump 121 and the second connection bump 122 may include different materials. For example, the first connection bump 121 may be a pillar structure containing copper (Cu), and the second connection bump 122 may be a spherical structure containing solder. Depending on the embodiment, either the first connection bump 121 or the second connection bump 122 may be omitted. An underfill layer 125 may be disposed between the semiconductor chip 120 and the lower redistribution structure 110. The underfill layer 125 may include an insulating resin, such as epoxy resin, and may physically and electrically protect the first connection bump 121 and the second connection bump 122. The underfill layer 125 may have a capillary underfill (CUF) structure, but the present inventive concept is not limited thereto. Depending on the embodiment, the underfill layer 125 may have a molded underfill (MUF) structure integrated with the encapsulant 140.

The encapsulant 140 may encapsulate at least a portion of the semiconductor chip 120 on an upper surface of the redistribution structure 110. The encapsulant 140 may include, for example, a thermosetting resin such as an epoxy resin, a thermoplastic resin such as polyimide, or a prepreg impregnated with an inorganic filler in these resins, ABF, FR-4, BT, and an Epoxy Molding Compound (EMC). For example, the encapsulant 140 may include EMC.

In various embodiments, the interconnection structure 130 may extend through the encapsulant 140 to electrically connect the lower redistribution layers 112 and the upper redistribution layers 152. The interconnection structure 130 may extend in a vertical direction (Z-direction) within the encapsulant 140. An upper surface of the interconnection structure 130 may be exposed from the encapsulant 140, and may be substantially coplanar with an upper surface of the encapsulant 140. For example, the interconnection structure 130 may have a post shape penetrating through the encapsulant 140; however, the shape of the interconnection structure 130 is not limited thereto. The interconnection structure 130 may include a metal material, such as copper (Cu). Depending on the embodiment, a lower seed layer containing titanium (Ti), copper (Cu), and the like may be disposed on a lower surface of the interconnection structure 130.

In various embodiments, the upper redistribution structure 150 may be disposed on the semiconductor chip 120 and the encapsulant 140, and may include an upper insulating layer 151, upper redistribution layers 152, and upper redistribution vias 153. The upper redistribution layers 152 may include a metal structure 155.

In various embodiments, the upper insulating layer 151 may include an insulating resin, where the insulating resin may include a thermosetting resin, such as an epoxy resin, a thermoplastic resin, such as polyimide, or a resin impregnated with an inorganic filler, etc., such as prepreg, ABF, FR-4, BT, or PID. The upper insulating layer 151 may include a plurality of layers stacked in a vertical direction (Z-axis direction). Depending on the process, boundaries between the plurality of layers may be indistinct.

In various embodiments, the upper redistribution layers 152 may be disposed on or within the upper insulating layer 151, and may redistribute the interconnection structure 130. The upper redistribution layer 152 may include, for example, copper (Cu), aluminum (Al), silver (Ag), tin (Sn), gold (Au), nickel (Ni), lead (Pb), titanium (Ti), or a metal material including an alloy thereof. The upper redistribution layers 152 may include more or fewer redistribution layers than shown in the drawing.

In various embodiments, the upper redistribution layers 152 may include a metal structure 155 disposed on an upper surface of the upper insulating layer 151.

In various embodiments, a metal structure 155, that may be included in the upper redistribution structure 150, may have a first surface 155U1 in contact with the metal plate 160, a second surface 155U2 around the first surface 155U1, and a third surface 155U3 around the second surface 155U2, wherein the third surface 155U3 is located on a level higher than that of the second surface 155U2. A leak phenomenon of the metal plate 160, when forming the metal plate 160, and occurrence of a crack in a resist (e.g., DFR; Dry Film Resist) used in the process may be prevented, so that reliability may be improved.

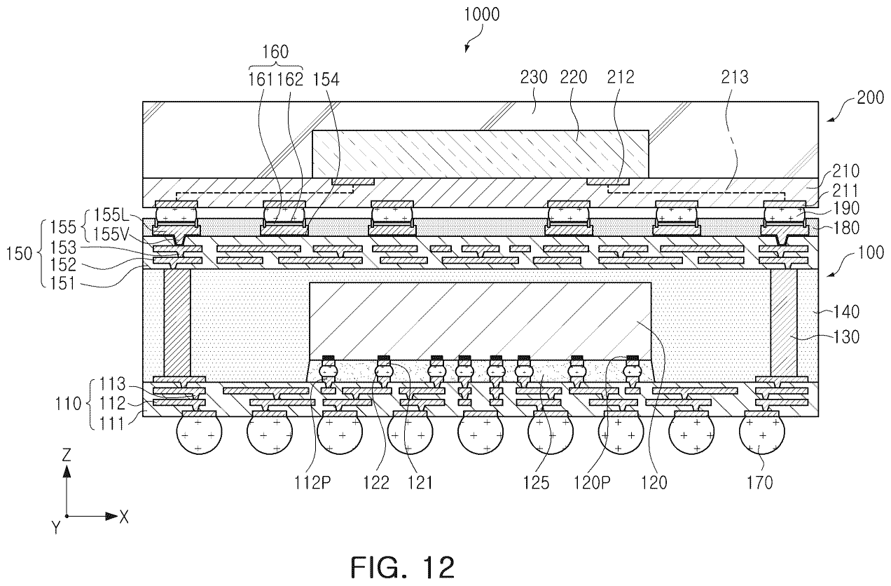

In various embodiments, the metal structure 155 may be physically and electrically connected to an external device (see FIG. 12). The metal structure 155 may include a metal layer portion 155L on the upper surface 155U of the upper insulating layer 151 and a metal via portion 155V extending from the metal layer portion 155L to an interior of the upper insulating layer 151. The metal via portion 155V may be in electrical contact with the upper redistribution layer 152 and upper redistribution vias 153 within the upper insulating layer 151, and may be electrically connected to the interconnection structure 130. In various embodiments, the metal via portion 155V may be in direct contact and/or electrical contact with the interconnection structure 130. There may be a plurality of metal structures 155, where a metal structure 155 having the metal via portion 155V and a metal structure 155 without having the metal via portion 155V may coexist. The metal structure 155 having the metal via portion 155V may be composed of only the metal layer portion 155L. Depending on the embodiment, all of the plurality of metal structures 155 may include a metal via portion 155V. Depending on the embodiment, not all of the plurality of metal structures 155 may include the metal via portion 155V. At least a portion of the metal structures 155 not including the metal via portion 155V may be electrically connected to the upper redistribution layers 152 through metal vias extending into the upper insulating layer 151 in regions not shown in the drawings.

In various embodiments, the metal structure 155 may include a first surface 155U1 on which the metal plate 160 is disposed, a second surface 155U2 around the first surface 155U1, and a third surface 155U3 around the second surface 155U2. The third surface 155U3 may be located on a level higher than that of the second surface 155U2. The second surface 155U2 may be located on a level lower than that of the third surface 155U3, and may be located on a level lower than that of the first surface 155U1. The first surface 155U1 may be located at substantially the same level as the third surface 155U3. The second surface 155U2 of the metal structure 155 may form a trench portion, the first surface 155U1 may be defined as a first portion, and the third surface 155U3 may be defined as a second portion. In this case, the metal structure 155 may be defined as including a first portion in which the metal plate 160 is disposed, a second portion around the first portion, and a trench portion between the first portion and the second portion, where the trench portion can separate the first portion from the second portion.

As the third surface 155U3 of the metal structure 155 is located on a level higher than that of the second surface 155U2, a leak phenomenon in which a portion of metal is thinly formed in regions other than a target location when forming the metal plate 160 may be prevented, and a crack phenomenon of a resist (e.g., DFR; Dry Film Resist) due to the leak phenomenon may be prevented, so that a semiconductor package with improved reliability may be provided.

As illustrated in FIG. 2B, an upper surface 155U of the metal structure 155 may be circular, but the present inventive concept is not limited thereto. Depending on the embodiment, the upper surface 155U of the metal structure 155 may have an oval or polygonal shape.

In various embodiments, a width D1 of the second surface 155U2 may be about 0.5 micrometers (μm) to about 5 μm. Depending on the embodiment, the width D1 of the second surface 155U2 may be about 0.5 μm to about 3 μm, or about 1 μm to about 5 μm, or about 1 μm to about 3 μm. When the width D1 of the second surface 155U2 is about 0.5 μm or less, it may be difficult to form a fine pattern and an effect of preventing the crack phenomenon may be reduced. When the width D1 in a horizontal direction is about 5 μm or more, an effect of preventing the leak phenomenon may be reduced, and an effect of preventing the crack phenomenon may be reduced.

In various embodiments, a level difference H1 between the second surface 155U2 and the third surface 155U3 may be substantially equal to the width D1 of the second surface 155U2, but the present inventive concept is not limited thereto. The level difference H1 between the second surface 155U2 and the third surface 155U3 may be about 0.5 μm to about 5 μm. Depending on the embodiment, the level difference H1 between the second surface 155U2 and the third surface 155U3 may be about 0.5 μm to about 3 μm, or about 1 μm to about 5 μm, or about 1 μm to 3 μm. When the level difference H1 between the second surface 155U2 and the third surface 155U3 is about 0.5 μm or less, the effect of preventing the leak phenomenon and crack phenomenon may be reduced. When the level difference HI between the second surface 155U2 and the third surface 155U3 is about 5 μm or more, the stability of the metal structure 155 may be reduced.

In various embodiments, the metal structure 155 may include, for example, a metal material including copper (Cu), aluminum (Al), titanium (Ti), or an alloy thereof. There may be a plurality of metal structures 155, as illustrated in the drawing, which may include more or fewer metal structures 155 than those illustrated in the drawing.

In various embodiments, the upper redistribution vias 153 may penetrate through the upper insulating layer 151 and be electrically connected to the upper redistribution layer 152. For example, the upper redistribution vias 153 may interconnect upper redistribution layers 152 on different levels. The upper redistribution vias 153 may interconnect the upper redistribution layer 152 and the interconnection structure 130. In various embodiments, the upper redistribution vias 153 may be filled vias in which an interior of a via hole is filled with a metal material, or may be conformal vias in which a metal material extends along an inner wall of the via hole. The upper redistribution vias 153 may include, for example, copper (Cu), aluminum (Al), silver (Ag), tin (Sn), gold (Au), nickel (Ni), lead (Pb), titanium (Ti), or alloys thereof.

In various embodiments, the metal plate 160 may be disposed on an upper surface 155U of the metal structure 155. The metal plate 160 may be disposed to be in contact with a first surface 155U1 of the upper surface 155U of the metal structure 155, and may be in contact with the second surface 155U2 and the third surface 155U3.

In various embodiments, the metal plate 160 may include a plurality of layers, where a first metal plate layer 161 may be in contact with the metal structure 155 and a second metal plate layer 162 may be on an upper surface of the first metal plate layer 161. The first metal plate layer 161 and the second metal plate layer 162 may have substantially the same width in a horizontal direction (e.g., X-direction or Y-direction). A thickness of the second metal plate layer 162 in a vertical direction (Z-direction) may be less than a thickness of the first metal plate layer 162 in the vertical direction (Z-direction). Depending on the embodiment, the thickness of the second metal plate layer 162 may be substantially the same as the thickness of the first metal plate layer 161, or the thickness of the second metal plate layer 162 may be greater than the thickness of the first metal plate layer 161.

In various embodiments, the metal plate 160 may include nickel (Ni) and/or gold (Au), where for example, the first metal plate layer 161 may include nickel (Ni), and the second metal plate layer 162 may include gold (Au).

In various embodiments, a metal seed layer 154 may be disposed on a lower surface of the metal structure 155, where the metal seed layer 154 may be in contact with the upper insulating layer 151 on the lower surface of the metal structure 155. When the metal structure 155 includes a metal via portion 155V, the metal seed layer 154 may be formed to cover a metal layer portion 155L and a metal via portion 155V between the upper insulating layer 151 and the metal structure 155. The metal seed layer 154 may have a conformal form in which a metal material extends into the interior of a via hole of the upper insulating layer 151 along an inner wall of the via hole. The metal seed layer 154 may include titanium (Ti) and/or copper (Cu).

In various embodiments, the connection bumps 170 may be disposed on a lower surface of the lower redistribution structure 110. The connection bumps 170 may be electrically connected to the semiconductor chip 120 and the interconnection structure 130 through the lower redistribution layers 112. The semiconductor package 100 may be connected to an external device such as a module substrate or system board through the connection bumps 170. The connection bumps 170 may include a low-melting point metal, for example, tin (Sn) or a tin-silver-copper (Sn—Ag—Cu) alloy containing tin (Sn) or a tin-aluminum-copper (Sn—Al—Cu) alloy, or the like. The connection bumps 170 may have a shape that is a combination of a pillar (or underbump metal) and a ball. The pillar may include copper (Cu) or an alloy of copper (Cu), and the ball may include a solder ball. Depending on the embodiment, the lower insulating layer 111 may include a resist layer protecting the connection bumps 170 from external physical and chemical damage.

In various embodiments, the passivation layer 180 may be disposed on the upper redistribution structure 150, and cover at least a portion of the metal structure 155. The passivation layer 180 may be contact an entirety of the side surfaces of the metal structure 155 and at least a portion of the third surface 155U3 of the metal structure 155. The passivation layer 180 may not cover an upper surface of the metal plate 160, so that the upper surface of the metal plate 160 is exposed. The passivation layer 180 may not contact a side surface of the metal plate 160. The upper surface of the passivation layer 180 may be located on a level higher than that of the upper surface of the metal plate 160. Depending on the embodiment, the passivation layer 180 may not contact the metal structure 155. An opening in which the passivation layer 180 does not cover the upper redistribution structure 150 may be formed in various sizes. Depending on the size of the opening, a degree to which the passivation layer 180 contacts the metal structure 150 may vary. Depending on the embodiment, the opening may be formed to be sufficiently large that the passivation layer 180 does not contact the metal structure 155. The passivation layer 180 may protect the upper redistribution structure 150 from external physical and chemical damage. The passivation layer 180 may include an insulating material, such as prepreg, Ajinomoto Build-up Film (ABF), FR-4, Bismaleimide Triazine (BT) solder resist, or Photo Solder Resist (PSR).

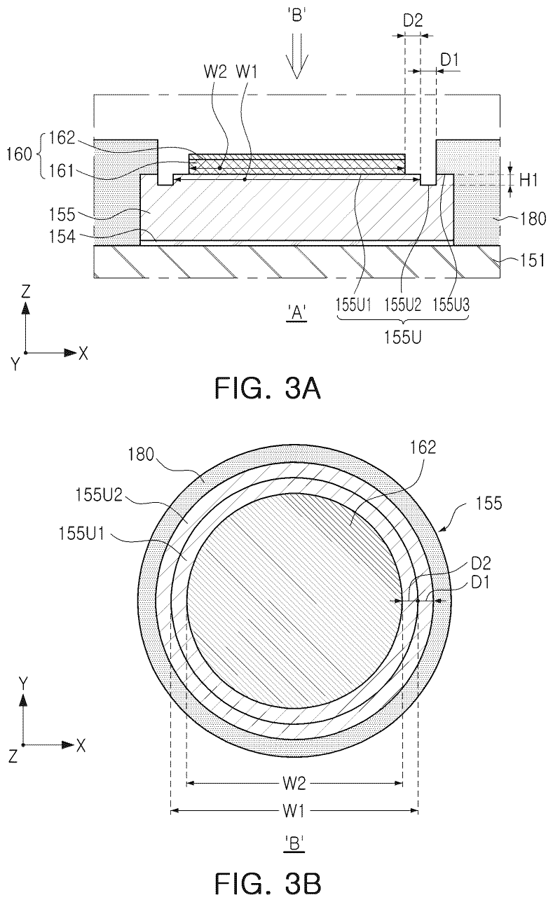

FIG. 3A and 3B are an enlarged view of region ‘A’ of FIG. 1 according to example embodiments, where FIG. 3A is a cross-sectional view of region ‘A’ and FIG. 3B is a plan view of FIG. 3A.

Referring to FIG. 3A, a metal plate 160 may be disposed to cover a portion of a first surface 155U1 of the metal structure 155, where a width W2 of the metal plate 160 may be smaller than a width WI of the first surface 155U1 of the metal structure 155. The width D2 of an exposed portion of the first surface 155U1 of the metal structure 155, not in contact with the metal plate 160 may be substantially the same as the width D1 of the second surface 155U2, but the present inventive concept is not limited thereto. Depending on the embodiment, the width D2 of the portion of the first surface 155U1 of the metal structure 155, not in contact with the metal plate 160 may be smaller than the width DI of the second surface 155U2, or the width D2 of the portion of the first surface 155U1 of the metal structure 155, not in contact with the metal plate 160 may be greater than the width D1 of the second surface 155U2.

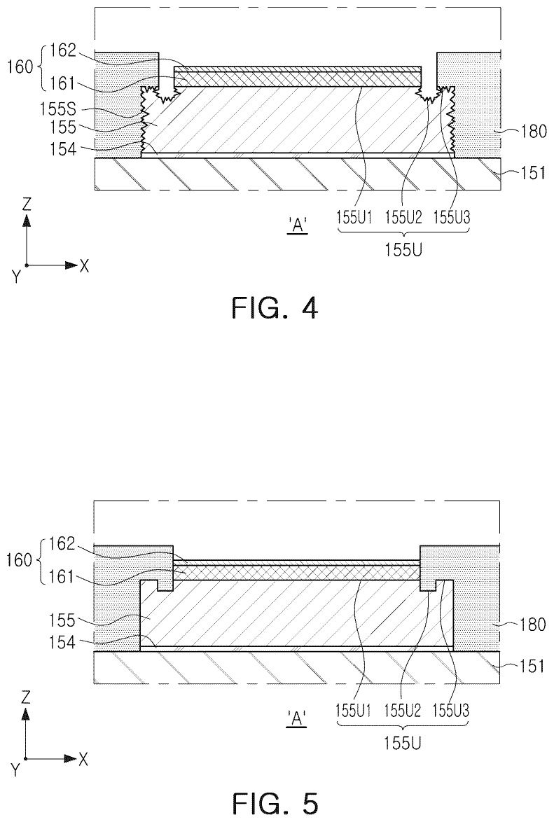

FIGS. 4 to 10 are enlarged views of region ‘A’ in FIG. 1 according to example embodiments.

Referring to FIG. 4, at least a portion of an upper surface 155U and a side surface of the metal structure 155 may have an uneven surface 155S, which is irregularly etched and has a rough shape. Among surfaces of the metal structure 155, a portion having the uneven surface 155S may include a portion in contact with a passivation layer 180. As a contact area between the metal structure 155 and the passivation layer 180 becomes greater, adhesion between the metal structure 155 and the passivation layer 180 improves, thereby improving reliability.

Referring to FIG. 5, the passivation layer 180 may be disposed to cover the third surface 155U3 and the second surface 15502 of the metal structure 155. The passivation layer 180 may be disposed to contact a side surface the metal plate 160. The passivation layer 180 may be disposed to contact the second surface 155U2, the third surface 155U3 of the metal structure 155, and the side surface of the metal plate 160, so that the passivation layer 180 protects the upper redistribution structure 150 from external physical and chemical damage.

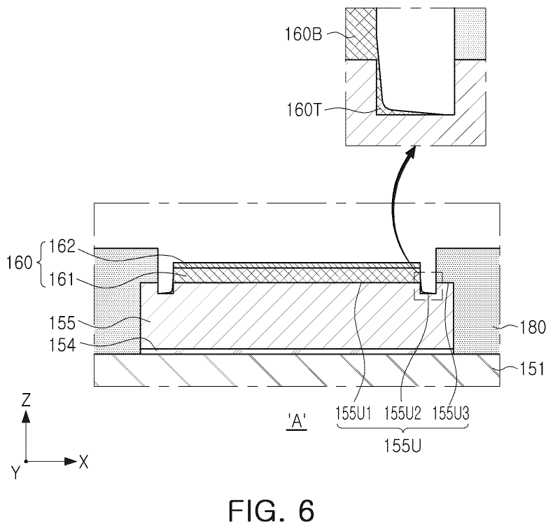

Referring to FIG. 6, the metal plate 160 may include a body portion 160B disposed on the first surface 155U1 of the metal structure 155 and a tail portion 160T extending from a lower portion of the body portion 160B and covering at least a portion of the second surface 155U2 of the metal structure 155. The tail portion 160T may cover a side surface formed by a level difference between the first surface 155U1 and the second surface 155U2 of the metal structure 155. Depending on the embodiment, the tail portion 160T may cover an entirety of the second surface 155U2 of the metal structure 155, and the tail portion 160T may cover at least a portion of the side surface formed by a level difference between the second surface 155U2 and the third surface 155U3 of the metal structure 155.

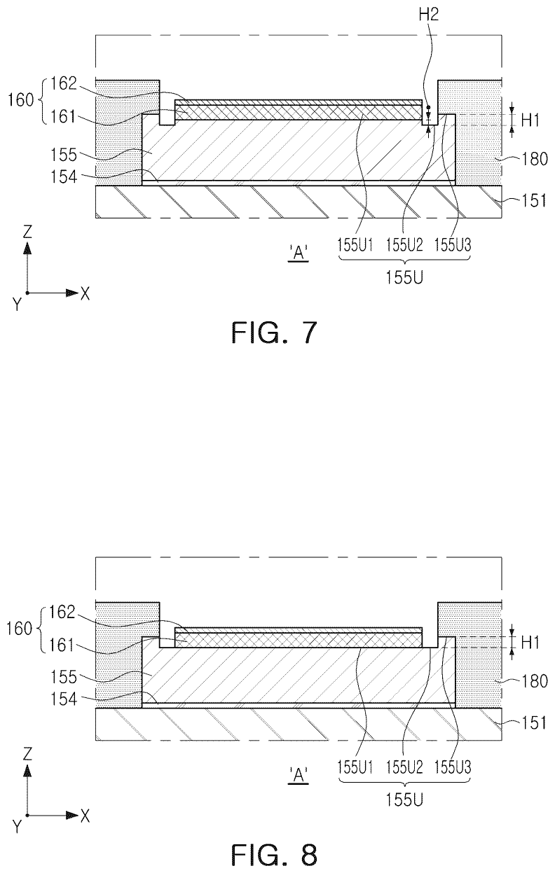

Referring to FIG. 7, a level of the first surface 155U1 of the metal structure 155 may be higher than that of the second surface 155U2, and lower than that of the third surface 155U3. Accordingly, a difference in levels H2 between the first surface 155U1 and the second surface 155U2 may be less than a difference in levels H3 between the second surface 155U2 and the third surface 155U3. An upper surface of the metal plate 160 may be located on a level higher than that of the third surface 155U3 of the metal structure 155.

Referring to FIG. 8, the first surface 155Ul and the second surface 155U2 of the metal structure 155 may be located on substantially the same level. The upper surface of the metal plate 160 may be located on a level higher than that of the third surface 155U3 of the metal structure 155.

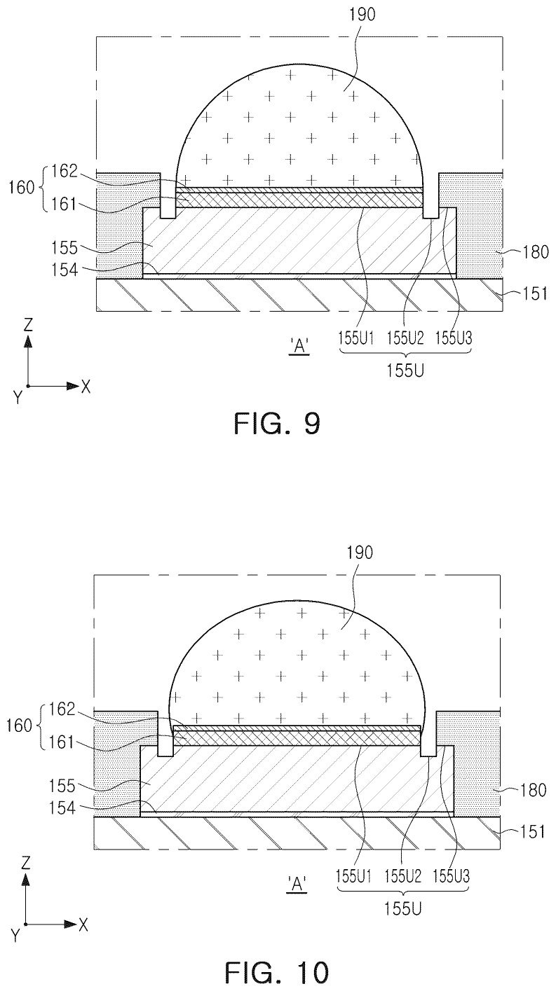

Referring to FIG. 9, a connection metal body 190 may be disposed on an upper surface of the metal plate 160. The upper redistribution structure 150 may be physically and/or electrically connected to an external device through a metal plate 160 and a connection metal body 190 (see FIG. 12). The connection metal body 190 may include a low melting point metal, for example, tin (Sn) or a tin-silver-copper (Sn—Ag—Cu) alloy containing tin (Sn) or tin-aluminum-copper (Sn-Al).-Cu) alloy, or the like. Depending on the embodiment, the connection metal body 190 may have a shape that combines a pillar (or underbump metal) and a ball. The pillar may include copper (Cu) or an alloy of copper (Cu), and the ball may include a solder ball.

Referring to FIG. 10, the connection metal body 190 may be disposed to cover an entirety of the metal plate 160 and a portion of a side surface of the metal plate 160. The connection metal body 190 may be spaced apart from the metal structure 155 and the passivation layer 180.

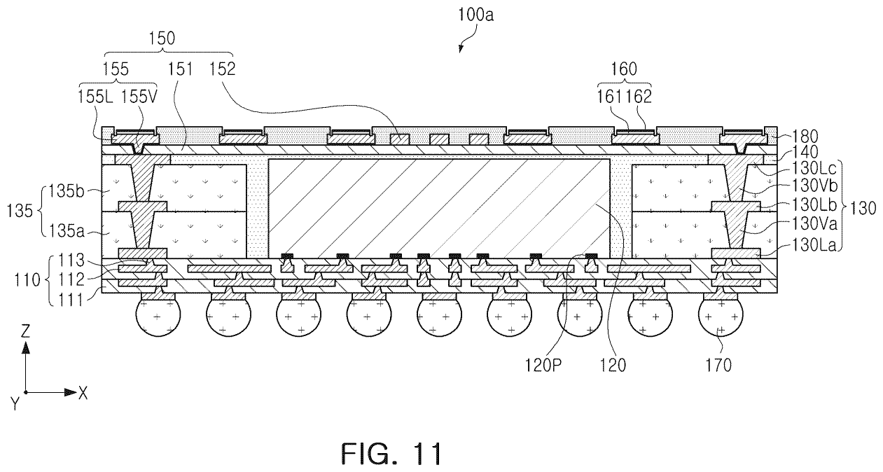

FIG. 11 is a cross-sectional view illustrating a semiconductor package according to example embodiments.

Referring to FIG. 11, a semiconductor package 100a may further include an intermediate insulating layer 135 covering at least a portion of the interconnection structure 130. The intermediate insulating layer 135 may include a first intermediate insulating layer 135a disposed on an upper surface of the lower redistribution structure 110 and a second intermediate insulating layer 135b disposed on an upper surface of the first intermediate insulating layer 135a. The interconnection structure 130 may include a first intermediate wiring layer 130La buried in a lower surface of the first intermediate insulating layer 135a, a second intermediate wiring layer 130 Lb disposed on an upper surface of the first intermediate insulating layer 135a, a third intermediate wiring layer 130Lc disposed on an upper surface of the second insulating layer, a first wiring via 130Va penetrating through the first intermediate insulating layer 135a and electrically connecting the first and second intermediate wiring layers 130La and 130Lb, and a second wiring via 130Vb penetrating through the second intermediate insulating layer 135b and electrically connecting the second and third intermediate wiring layers 130Lb and 130Lc. The encapsulant 140 may cover at least a portion of the intermediate insulating layer 135, where an upper surface of the encapsulant 140 and an upper surface of the third intermediate wiring layer 130Lc may be located on substantially the same surface (the surfaces may be coplanar). Other configurations not specifically described herein may have substantially the same characteristics as the configurations of the semiconductor package 100 of FIG. 1.

FIG. 12 is a cross-sectional view illustrating a semiconductor package according to example embodiments.

Referring to FIG. 12, a semiconductor package 1000 according to an embodiment may include a first package 100 and a second package 200. The first package 100 is illustrated to be the same as the semiconductor package 100 illustrated in FIG. 1, but may be replaced with semiconductor packages having the characteristics described with reference to the enlarged views of FIGS. 2 to 10 or the same characteristics as the semiconductor package 100a of FIG. 11.

In various embodiments, the second package 200 may include a redistribution substrate 210, a second semiconductor chip 220, and a second encapsulant 230. The redistribution substrate 210 may include a lower pad 211, which is physically and electrically connected to the connection metal body 190 of the first semiconductor package 100 on a lower surface thereof. The redistribution substrate 210 may include an upper pad 212 which is physically and electrically connected to the second semiconductor chip 220 on an upper surface thereof. The redistribution substrate 210 may include a redistribution circuit 213 electrically connecting the lower pad 211 and the upper pad 212, where the second semiconductor chip 220 can be electrically connected to the upper redistribution structure 150 through the redistribution substrate 210. In various embodiments, the connection metal body 190 may be electrically connected to the redistribution circuit 213 inside a second redistribution substrate 210 through the lower pad 211 of the redistribution substrate 210.

In various embodiments, the second encapsulant 230 may include the same or similar material as the encapsulant 140 of the first semiconductor package 100.

The semiconductor package 1000 according to the various embodiments may include a first package 100 having a structure in which the second surface 155U2 of the upper surface 155U of the metal structure 155 is located on a level lower than that of the third surface 155U3, so that a package on package (POP) having improved reliability may be implemented.

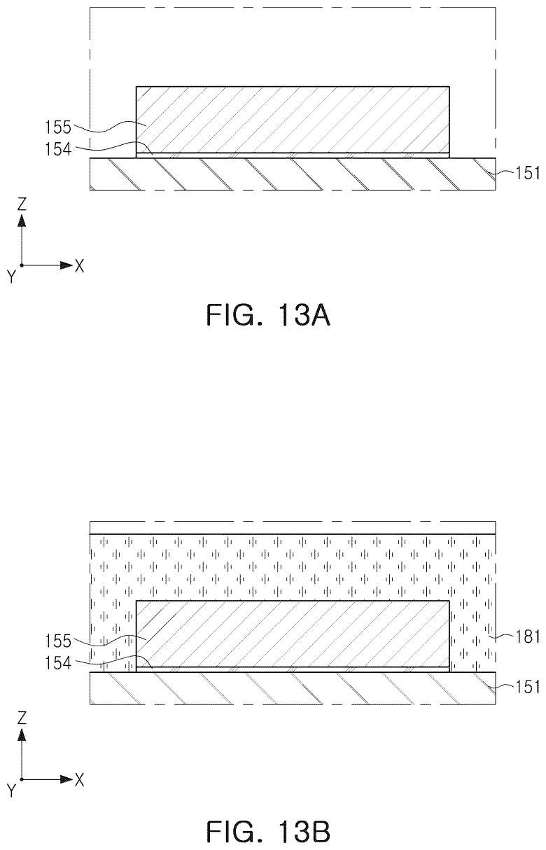

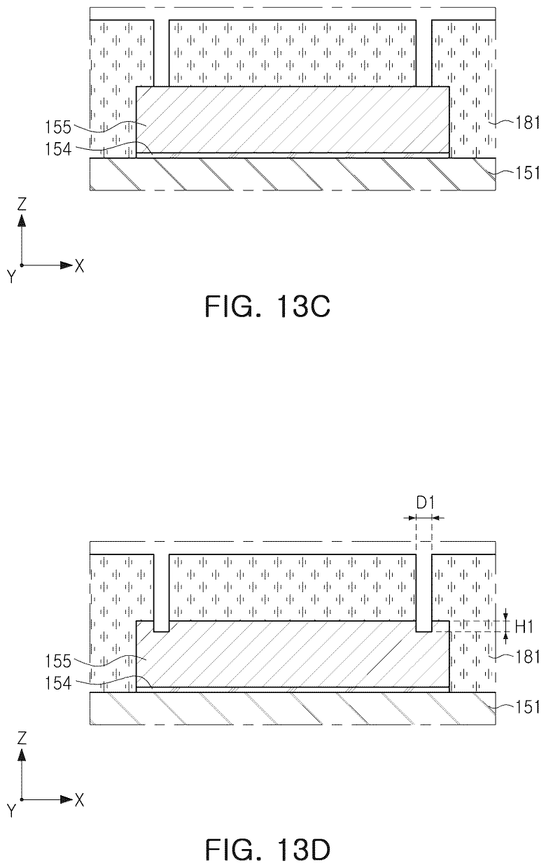

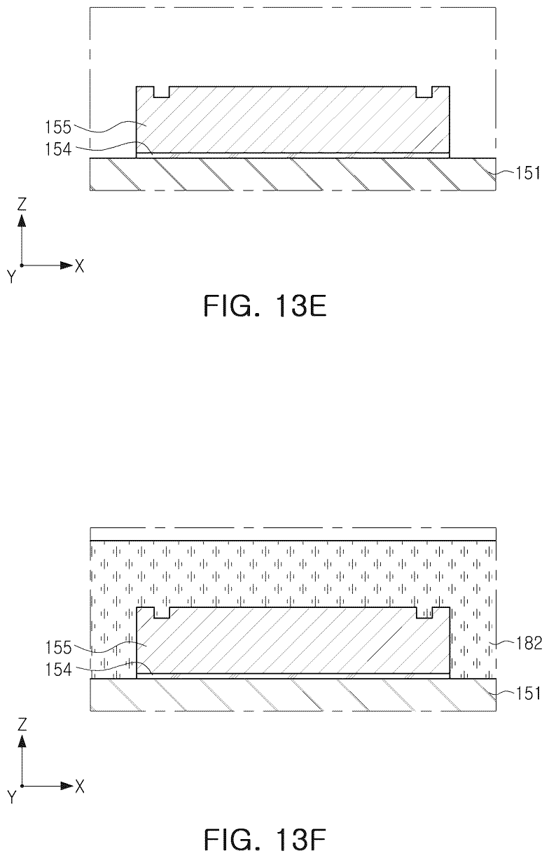

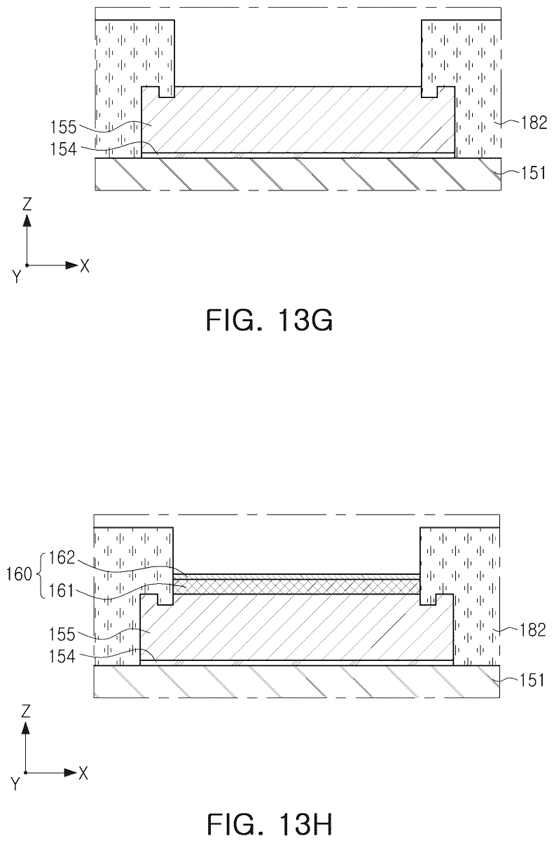

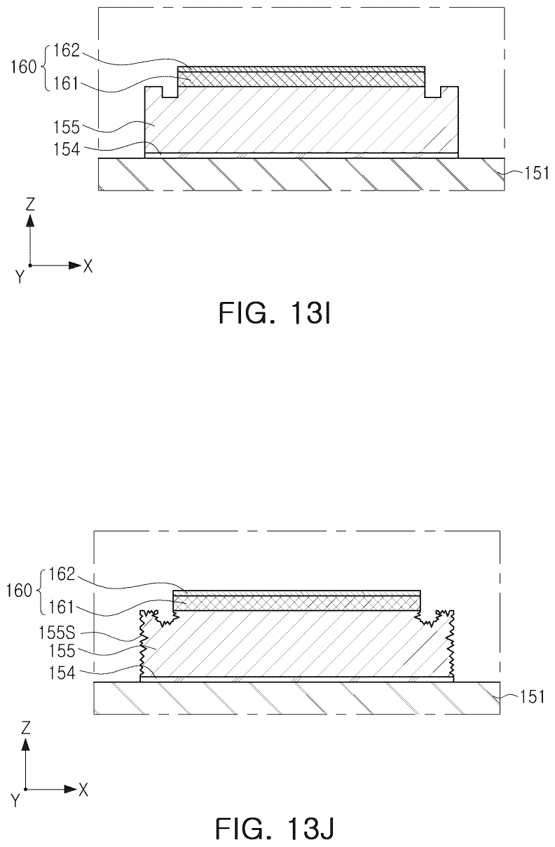

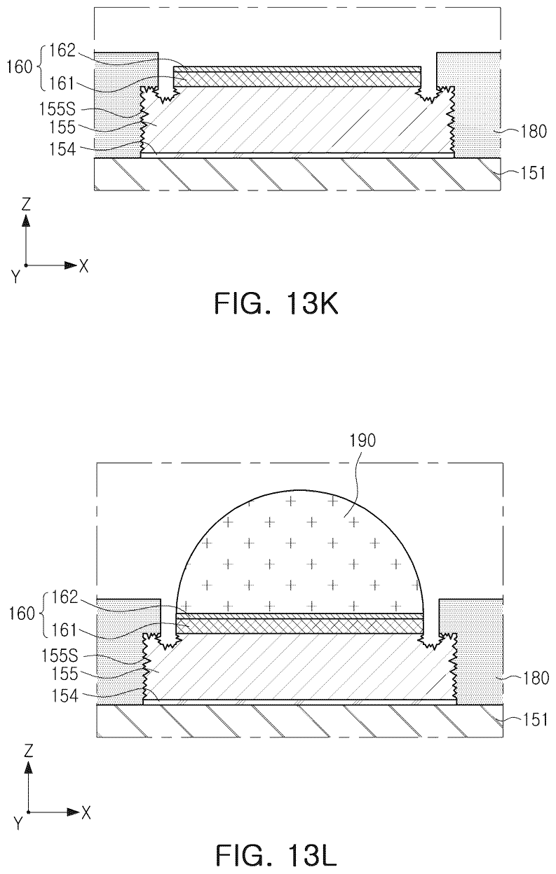

FIGS. 13A to 13L are enlarged views of region ‘A’ of FIG. 2A according to a process sequence to explain a manufacturing method for a semiconductor package according to example embodiments.

Referring to FIG. 13A, a metal seed layer 154 and a metal structure 155 may be formed sequentially on an upper insulating layer 151.

Referring to FIGS. 13B to 13D together with FIG. 2A and 2B, in order to form a second surface 155U2 located on a level lower than that of the surrounding area on the upper surface 155U of the metal structure 155, a process resist 181 may be formed to cover the insulating layer 151, the metal seed layer 154, and the metal structure 155. The process resist 181 may be, for example, dry film resist (DFR). A depth H1 at which the metal structure 155 is recessed may be about 0.5 μm to about 5 μm, to be described later correspond to a difference in levels between a second surface 155U2 and a third surface 155U3 of a metal structure 155. A width DI at which the metal structure 155 is recessed may be about 0.5 μm to about 5 μm, to be described later corresponds to the width of the second surface 155U2.

Referring to FIGS. 13E to 13F together with FIG. 2A and 2B, after forming the second surface 155U2 of the metal structure 155, an existing process resist 181 may be removed, and a new process resist 181 covering the upper insulating layer 151 and the metal structure 155 may be formed. The new process resist 182 may be, for example, dry film resist (DFR).

Referring to FIGS. 13G to 13I together with FIG. 2A and 2B, the new process resist 182 in a space for forming the metal plate 160 may be removed to expose a first surface 155U1 of the upper surface 155U of the metal structure 155. Thereafter, a metal plate 160 may be formed on the first surface 155U1. The metal plate 160 may include a plurality of layers by first forming a first metal plate layer 161 and forming a second metal plate layer 162 on the first metal plate layer 161. After forming the metal plate 160, the new process resist 182 may be removed.

Referring to FIGS. 13J to 13K together with FIGS. 2 and 4, a cubic zirconia etching (CZ) process may be performed to ensure that at least a portion of the upper surface 155U and a side surface of the metal structure 155 have an uneven surface 155S. Thereafter, a passivation layer 180 may be formed in contact with the upper surface of the upper insulating layer 151 and at least a portion of the uneven surface 155S of the metal structure 155. As the metal structure 155 has the uneven surface 155S, a contact surface with the passivation layer 180 is increased, so adhesion between the metal structure 155 and the passivation layer 180 may be improved, and the reliability of the semiconductor package may be improved.

Referring to FIG. 13L together with FIG. 12, a connection metal body 190 may be formed on an upper surface of the metal plate 160. The metal structure 155 may be electrically connected to an external device through the connection metal body 190.

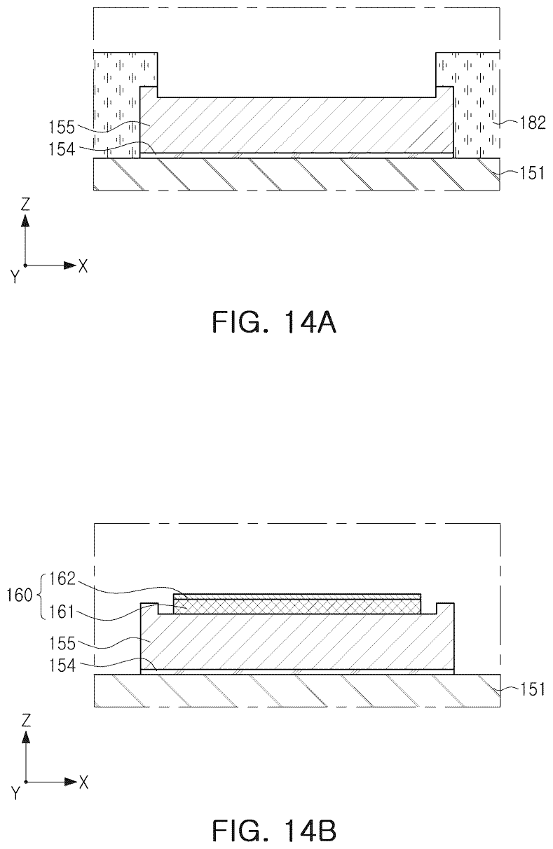

FIGS. 14A and 14B are enlarged views of region ‘A’ of FIG. 8 according to a process sequence to explain a method of manufacturing a semiconductor package according to example embodiments. In the following description, descriptions overlapping with those referring to FIGS. 13A to 13L will be omitted.

Referring to FIGS. 14A to 14B together with FIG. 8, a new process resist 182 may be removed to expose the remaining portion of the upper surface 155U of the metal structure 155 except for the third surface 155U3, and a metal plate 160 may be formed in the first region 155U1, which is a portion of the exposed upper surface 155U of the metal structure 155. Accordingly, as illustrated in FIG. 8, the first surface 155U1 and the second surface 155U2 of the metal structure 155 may be located at the same level.

As set forth above, according to example embodiments of the present inventive concept, a semiconductor package having improved reliability may be provided by disposing a metal plate on a metal structure including a trench structure.

The various and advantageous advantages and effects of the present inventive concept are not limited to the above description, and may be more easily understood in the course of describing the specific embodiments of the present inventive concept. While example embodiments have been shown and described above, it will be apparent to those skilled in the art that modifications and variations could be made without departing from the scope of the present inventive concept, as defined by the appended claims.

What is claimed is:

1. A semiconductor package, comprising:
a lower redistribution structure including lower redistribution layers;
a semiconductor chip on an upper surface of the lower redistribution structure, and electrically connected to the lower redistribution layers;
connection bumps on a lower surface of the lower redistribution structure, and electrically connected to the lower redistribution layers;
an upper redistribution structure, including an upper insulating layer on the semiconductor chip, an upper redistribution layers in the upper insulating layer, and a metal structure on the upper insulating layer;
an interconnection structure electrically connecting the lower redistribution layers and the upper redistribution layer; and
a metal plate on an upper surface of the metal structure,
wherein the upper surface of the metal structure has a first surface in contact with the metal plate, a second surface around the first surface, and a third surface around the second surface.

2. The semiconductor package of claim 1, further comprising:
a passivation layer on the upper redistribution layer, and covering at least a portion of the metal structure.

3. The semiconductor package of claim 2, wherein the first surface is located on a level the same as or higher than that of the second surface, and the third surface is located on a level higher than that of the second surface, and wherein
the passivation layer is in contact with the second surface of the metal structure and a side surface of the metal plate.

4. The semiconductor package of claim 1, wherein at least a portion of each of the upper surface and side surface of the metal structure has an uneven surface.

5. The semiconductor package of claim 1, further comprising:
an intermediate insulating layer covering at least a portion of the interconnection structure,
wherein the intermediate insulating layer includes a first intermediate insulating layer disposed on the upper surface of the lower redistribution structure and a second intermediate insulating layer disposed on an upper surface of the first intermediate insulating layer,
wherein the interconnection structure includes a first intermediate wiring layer in a lower surface of the first intermediate insulating layer, a second intermediate wiring layer on an upper surface of the first intermediate insulating layer, a third intermediate wiring layer on an upper surface of the second intermediate insulating layer, a first wiring via penetrating through the first intermediate insulating layer and connecting the first and second intermediate wiring layers, and a second wiring via penetrating through the second intermediate insulating layer and electrically connecting the second and third intermediate wiring layers.

6. The semiconductor package of claim 1, wherein the metal plate comprises a body portion disposed on the first surface of the metal structure, and a tail portion extending from a lower portion of the body portion to cover at least a portion of the second surface of the metal structure.

7. The semiconductor package of claim 1, wherein a width of the metal plate is smaller than a width of the first surface of the metal structure.

8. The semiconductor package of claim 1, wherein the first surface of the metal structure is located on a same level the third surface.

9. The semiconductor package of claim 1, further comprising:
a seed metal layer on a lower surface of the metal structure and in contact with the upper insulating layer.

10. The semiconductor package of claim 1, wherein the metal structure comprises a metal layer portion on the upper insulating layer, and a metal via portion extending from the metal layer portion into the upper insulating layer.

11. The semiconductor package of claim 1, wherein a width of the second surface of the upper surface of the metal structure is about 0.5 μm to about 5 μm.

12. The semiconductor package of claim 1, wherein a level difference between the third surface and the second surface of the metal structure is about 0.5 μm to about 5 μm.

13. The semiconductor package of claim 1, wherein the metal structure comprises at least one of copper (Cu), aluminum (Al), and titanium (Ti), and
the metal plate comprises at least one of nickel (Ni) and gold (Au).

14. A semiconductor package, comprising:
a semiconductor chip;
a lower redistribution structure including a lower insulating layer on a lower surface of the semiconductor chip, and lower redistribution layers electrically connected to the semiconductor chip on the lower surface of the semiconductor chip;
connection bumps on a lower surface of the lower redistribution structure, and electrically connected to the lower redistribution layers;
an encapsulant covering at least a portion of the semiconductor chip on an upper surface of the lower redistribution structure;
an upper insulating layer on the encapsulant;
upper redistribution layers including a metal structure on the upper insulating layer;
a metal plate on the metal structure; and
an interconnection structure penetrating through the encapsulant and electrically connecting the lower redistribution layers and the upper redistribution layers,
wherein the metal structure includes a first surface in contact with the metal plate, a second surface around the first surface, and a third surface surrounding the second surface and having a step difference from the second surface.

15. The semiconductor package of claim 14, wherein the second surface of the metal structure is located on a level lower than that of the third surface.

16. The semiconductor package of claim 14, wherein the second surface of the metal structure is located on a level lower than that of the first surface.

17. The semiconductor package of claim 14, further comprising:
a passivation layer on the upper insulating layer, and in contact with a side surface of the metal structure and the third surface of the metal structure.

18. A semiconductor package, comprising:
a lower redistribution structure including lower redistribution layers;
a semiconductor chip on the lower redistribution structure, and electrically connected to the lower redistribution layers;
connection bumps below the lower redistribution structure, and electrically connected to the lower redistribution layers;
an encapsulant covering at least a portion of the semiconductor chip on the lower redistribution structure;
an upper redistribution structure including an upper insulating layer on the encapsulant, and upper redistribution layers including a metal structure on the upper insulating layer;
a metal plate on the metal structure; and
an interconnection structure penetrating through the encapsulant and electrically connecting the lower redistribution layers and the upper redistribution layers,
wherein the metal structure has a first portion in contact with the metal plate and a second portion surrounding the first portion,
wherein first portion and the second portion are spaced apart from each other.

19. The semiconductor package of claim 18, wherein the metal structure further comprises a trench portion between the first portion and the second portion, and
an upper surface of the trench portion of the metal structure is located on a level lower than that of an upper surface of the second portion of the metal structure.

20. The semiconductor package of claim 18, further comprising:
a passivation layer on the upper insulating layer,
wherein the passivation layer is in contact with an entirety of side surfaces of the metal structure and at least a portion of the second portion of the metal structure.
